(19) United States
(12) Patent Application Publication
(10) Pub. No.: US 2013/0222046 A1
(43) Pub. Date: Aug. 29, 2013

(54) MODIFIED BINARY SEARCH FOR TRANSFER FUNCTION ACTIVE REGION

(71) Applicant: Fairchild Semiconductor Corporation, (US)

(72) Inventor: Igor Furlan, Sunnyvale, CA (US)

(73) Assignee: Fairchild Semiconductor Corporation, San Jose, CA (US)

(21) Appl. No.: 13/767,528

(22) Filed: Feb. 14, 2013

Related U.S. Application Data
(60) Provisional application No. 61/602,991, filed on Feb. 24, 2012.

(51) Int. Cl. B81B 7/00

(52) U.S. Cl. CPC B81B 7/008
USPC 327/516

(57) ABSTRACT

This document discusses, among other things, a modified binary search configured to identify monotonic transfer function active region boundaries. The modified binary search can avoid false results outside of the active region of the monotonic transfer function.

### CLAIM OF PRIORITY

This application claims the benefit of priority under 35 U.S.C. §119(e) of Furlan, U.S. Provisional Patent Application Ser. No. 61/602,991, entitled “MODIFIED BINARY SEARCH FOR TRANSFER FUNCTION ACTIVE REGION,” filed on Feb. 24, 2012 (Attorney Docket No. 2921.175PRV), which is hereby incorporated by reference herein in its entirety.

### BACKGROUND

Micro-electrical-mechanical systems (MEMS) represent a technology of small mechanical devices that, among other things, can be actuated electrically or can provide an electrical signal in response to a mechanical disturbance. In certain examples, the small size of MEMS devices make them particularly suited to use with or within mobile electronic devices. MEMS devices can save space and energy consumption over existing technologies and can also expand functionality of mobile electronic devices.

In an example, a mechanical response of a MEMS device to an electrical input (e.g., a voltage input) can be described by a transfer function with an associated active region. The active region of the transfer function bounds a input range that results in the desired mechanical response range. For input voltage changes occurring below or above the active region, there is a relatively small mechanical response.

In an example, the electrical response of a MEMS device to a mechanical disturbance can be described by a transfer function with an associated active region. The active region of a transfer function bounds a mechanical disturbance range that results in the desired electrical response. For input mechanical disturbances above or below the active region, there is a relatively small electrical response.

### OVERVIEW

This document discusses, among other things, a modified binary search configured to identify monotonic transfer function active region boundaries. Further, the modified binary search can avoid false results outside of the active region. This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example monotonic transfer function including an active region and one or more inactive regions.

FIG. 2 illustrates generally a flowchart of a binary search method to identify an input value corresponding to an end of an active region of a monotonic transfer function.

FIGS. 3A-E illustrate generally a monotonic transfer function and graphical representations of parameter values of first and second binary searches to identify input values associated with ends of an active region of the monotonic transfer function.

FIGS. 4A-E illustrate generally a monotonic transfer function and graphical representations of parameter values of first and second binary searches to identify input values associated with ends of an active region 401 of the monotonic transfer function.

FIG. 5 illustrates generally a flowchart of an example modified binary search method configured to identify an input value corresponding to an end of an active region associated with a monotonic transfer function.

FIG. 6 illustrates generally a flowchart of an example modified binary search method configured to identify an input value corresponding to an end of an active region associated with a monotonic transfer function.

FIGS. 7A-7C illustrates generally plots of an example modified binary search method.

FIG. 8 illustrates generally an example MEMS system.

### DETAILED DESCRIPTION

The present inventors have recognized, among other things, a modified binary search method for detecting monotonic transfer function active region boundaries, for example, for a MEMS lens actuator or other MEMS device. Many methods of detecting a transfer function active region use either a linear search or a binary search. In certain situations, a linear search can be more accurate than a binary search, but can also be more time-consuming. In some situations, a binary search can be more time efficient than a linear search, but can also be less accurate.

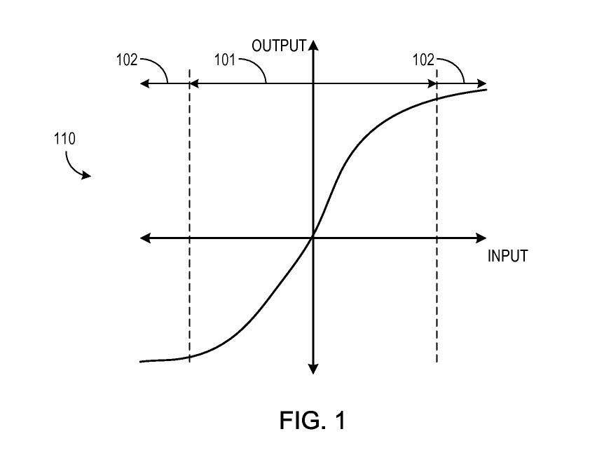

FIG. 1 illustrate generally an example monotonic transfer function 110 including an active region 101 and one or more inactive regions 102 along the path, or trajectory, of the transfer function 110. An inactive region 102 of a monotonic transfer function 110 can be asymptotic, in certain examples, and can be defined by a straight line that the monotonic transfer function approaches as the input of the monotonic transfer function 110 approaches infinity. The active region 101 can be the region of the monotonic transfer function 110 that lies between asymptotic regions of the monotonic transfer function 110.

### Binary Search Method

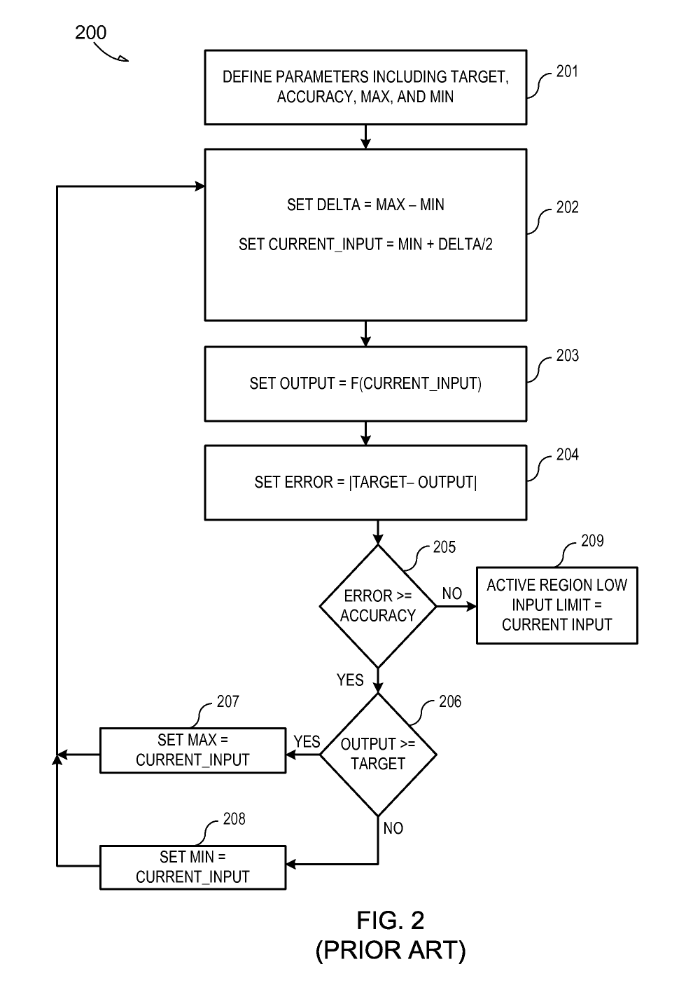

FIG. 2 illustrates generally a flowchart of a binary search method 200 to identify an input value corresponding to an end of an active region of a monotonic transfer function.

At 201, one or more parameters of the binary search method 200 can be set or selected, the one or more parameters including at least one of a target output value at the end of the active region (TARGET), an accuracy value (ACCURACY), a maximum input value at the end of the active region (MAX), or a minimum input value at an end of the active region (MIN). Since the exact nature of a monotonic transfer function may not be known, the parameters can be based on estimates of the input and output values that correspond to the extremes of the active region of the transfer function.

At 202, the binary search method 200 can determine a current input value (CURRENT_INPUT) as a value halfway between the maximum input value (MAX) and the minimum input value (MIN) of the active region of the transfer function. At 203, the binary search method 200 can apply the current input value (CURRENT_INPUT) as an input to the monotonic function and measure an output value (OUT). At 204, the binary search method 200 can calculate an error (ERR) as the absolute value of the difference between the target output value (TARGET) and the output value (OUT). At 205, the error (ERR) can be compared to the accuracy value (ACCURACY).

When the error (ERR), at 205, is greater than or equal to the accuracy value (ACCURACY), the binary search method 200, at 206, can compare the output value (OUT) to the target output value (TARGET). When the output value (OUT), at 206, is greater than or equal to the target output value (TARGET) (e.g., indicating that a target output value (TARGET) is greater than or equal to an output value (OUT) associated with previously set maximum input value (MAX)), the maximum input value (MAX), at 207, can be updated to be equal to the current input value (CURRENT_INPUT). Conversely, when the output value (OUT), at 206, is less than the target output value (TARGET) (e.g., indicating that a target output value (TARGET) is less than a previously set maximum input value (MAX)), the minimum input value (MIN), at 208, can be updated to be equal to the current input value (CURRENT_INPUT). After updating the maximum input value (MAX), at 207, or the minimum input value (MIN), at 208, the binary search method 200 can determine the current input value (CURRENT_INPUT) at 202.

When the error (ERR), at 205, is less than the accuracy value (ACCURACY), the binary search method 200, at 209, can indicate that the current input value (CURRENT_INPUT) corresponds to, or is associated with, an end of the active region of the monotonic function, such as a low input limit of the active region.

### Modified Binary Search Method

The modified binary search method disclosed herein can be more efficient than a linear search and more accurate than a binary search. Due to the flat regions (dead zones) of some monotonic transfer functions, results from a binary search performed on monotonic transfer functions, in certain examples, can be especially inaccurate. In an example, the modified binary search method disclosed herein can skip the flat region at the beginning and end of a monotonic transfer function and, accordingly, can identify monotonic transfer function active region boundaries quickly and reliably.

Detecting the mechanical-electrical transfer function active region boundaries of a MEMS device increase the efficiency and accuracy of MEMS based devices. In an example, improving active region detection speed and accuracy can shorten startup time, such as for various mobile products. In an example, a MEMS actuator can focus an optical device, such as a camera lens, in a mobile electronic device or accessory. The camera can be accurately, automatically focused when the transfer function defining the relationship between an applied voltage and a mechanical deflection of the MEMS actuator are known. In other examples, MEMS based devices can be used in other electronic devices for other purposes.

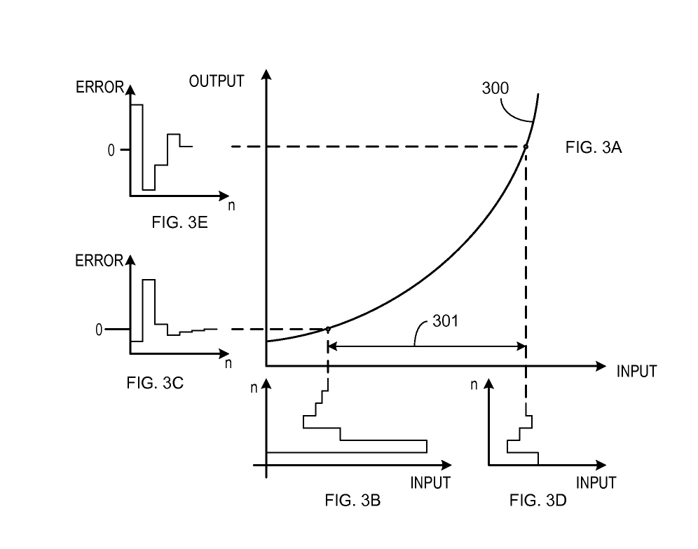

FIGS. 3A-E illustrate generally a monotonic transfer function 300 and graphical representations of parameter values of first and second binary searches (e.g., FIGS. 3B-3E) to identify input values associated with ends of an active region 301 of the monotonic transfer function. In an example, a binary search for a lowest input value corresponding to a first end of the active region 301 can update minimum and maximum input values (e.g., FIGS. 3B and 3C), calculate a current input value as the value halfway between the minimum input value and the maximum input value (e.g., FIG. 3B), apply the current input value to the monotonic transfer function to measure an output value, calculate an error using the output value and a target output value (e.g., FIG. 3C), and evaluate if the error is less than the accuracy value (not shown). If the error is not less than or equal to the accuracy value, one of the minimum or maximum input values can be updated with the current input value and another iteration (n) of the binary search can begin with calculating a new current input value. When the error is less than the accuracy value (e.g., FIG. 3C), the binary search can terminate and the current input value of the last iteration (n) can correspond to the lowest input value associated with the first end of the active region 301 (e.g., FIG. 3B).

In an example, a binary search for the highest input value corresponding to a second end of the active region 301 (e.g., FIGS. 3D and 3E) can update minimum and maximum input values, calculate a current input value as a value halfway between the minimum and maximum input values (e.g., FIG. 3D), apply the current input value to the monotonic transfer function 300 to measure an output value, calculate an error using the output value and a target output value (e.g., FIG. 3C), and evaluate if the error is less than an accuracy value (not shown). If the error is not less than or equal to the accuracy value, one of the minimum or maximum input values can be updated with the current input value and another iteration (n) of the binary search can begin with calculating a new current input value. When the error is less than the accuracy value (e.g., FIG. 3E), the search can terminate and the current input value of the last iteration (n) can correspond to the highest input value associated with the second end of the active region 301 of the monotonic transfer function 300 (e.g., FIG. 3D).

In some examples, where the general shape of the monotonic function may not be known, the initial minimum input value and the initial maximum input value of each binary search can be set at the extremes of the monotonic function or the extremes of the device being searched. In some examples, where the general shape and location of the active region are known, the initial maximum input value for a binary search of the low input value of an active region of a monotonic function can be set to a starting value within the active region. A subsequent binary search of the high input value of the active region can begin with the minimum input value set at the starting value within the active region used in the previous search. In some examples, where the general shape and location of the active region are known, the initial minimum input value for a binary search of the high input value of the active region of a monotonic function can be set to a starting value within the active region. A subsequent binary search of the low input value of the active region can begin with the maximum input value set at the starting value within the active region used in the previous search.

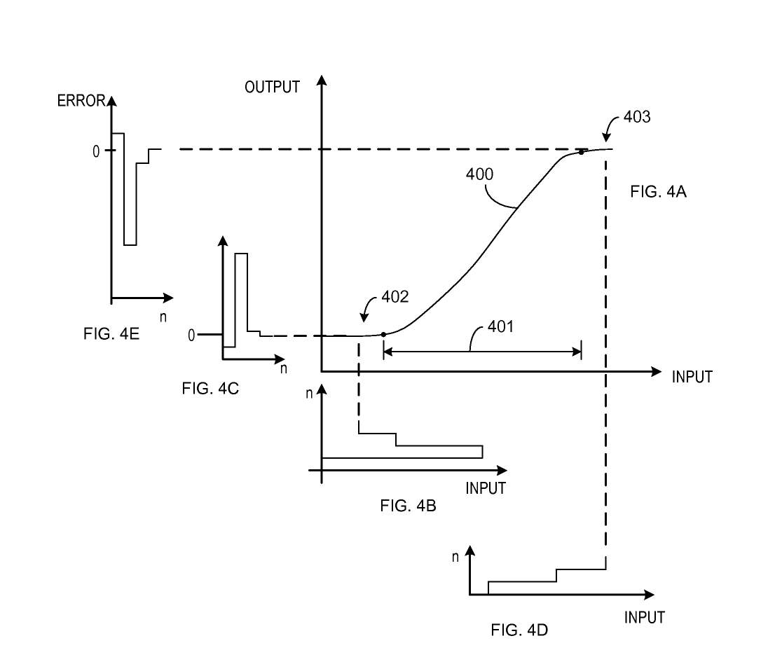

FIGS. 4A-E illustrate generally a monotonic transfer function 400 and graphical representations of parameter values of first and second binary searches (e.g., FIGS. 4B-4E) to identify input values associated with ends of an active region 401 of the monotonic transfer function. In an example, a binary search for a lowest input value corresponding to a first end of the active region 401 (e.g., FIGS. 4B and 4C) can update minimum and maximum input parameter values, calculate a current input value as the value halfway between the minimum input parameter and the maximum input parameter values (e.g., FIG. 4B), apply the current input to the monotonic transfer function to measure an output, calculate an error using the output and a target output value (e.g., FIG. 4C), and evaluate if the error is less than the accuracy parameter (not shown). If the error is not less than or equal to the accuracy, one of the minimum or maximum input parameters can be updated with the current input value and another iteration (n) of the binary search can begin with calculating a new current input. When the error is less than the accuracy parameter (e.g., FIG. 4C), the binary search can terminate and the current input value of the last iteration (n) can correspond to the lowest input value associated with the first end of the active region 401 (e.g., FIG. 4B). However, note that even though the first binary search found an input value associated with a first output value 402 that satisfied the accuracy comparison, the first output value 402 is significantly outside the true end of the active region 401, in certain examples, at least in part due to the asymptotic nature of the illustrated monotonic transfer function 400.

In an example, a binary search for the highest input value corresponding to a second end of the active region 401 (e.g., FIGS. 4D and 4E) can update minimum and maximum input values, calculate a current input as a value halfway between the minimum and maximum input values (e.g., FIG. 4D), apply the current input value to the monotonic transfer function 400 to measure an output value, calculate an error using the output value and a target output value (e.g., FIG. 4C), and evaluate if the error is less than an accuracy value (not shown). If the error is not less than or equal to the accuracy value, one of the minimum or maximum input values can be updated with the current input value and another iteration (n) of the binary search can begin with calculating a new current input value. When the error is less than the accuracy value (e.g., FIG. 4E), the search can terminate and the current input value of the last iteration (n) can correspond to the highest input value associated with the second end of the active region 401 of the monotonic transfer function 400 (e.g., FIG. 4D). However, note that even though the second binary search found an input value associated with a second output value 403 that can satisfy the accuracy comparison, the second output value 403 is significantly outside the true end of the active region 401, in certain examples, at least in part due to the asymptotic nature of the illustrated monotonic transfer function 400.

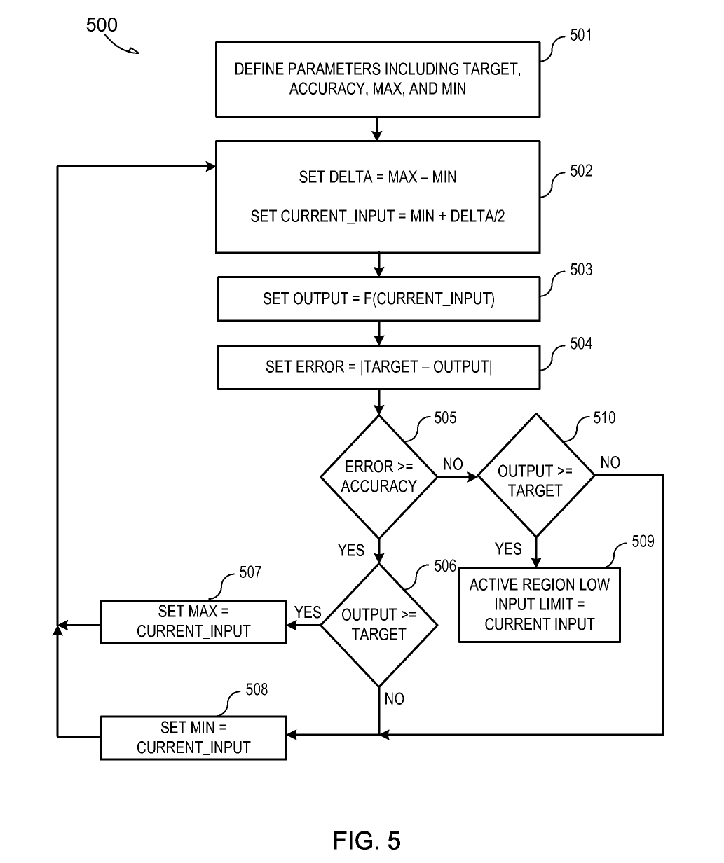

FIG. 5 illustrates generally a flowchart of an example modified binary search method 500 configured to identify an input value corresponding to an end of an active region associated with a monotonic transfer function. In the example of FIG. 5, the example modified binary search method 500 can search for a lowest input value associated with the active region. In contrast to the binary search method 200 discussed above with respect to FIG. 2, the modified binary search method 500 disclosed herein can include an additional decision step that can increase the accuracy of the results, especially with respect to monotonic transfer functions that include an asymptotic region.

At 501, one or more parameters can be set or selected including at least one of a target output value at the end of the active region (TARGET), an accuracy value (ACCURACY), a maximum input value at the end of the active region (MAX), or a minimum input value at an end of the active region (MIN). Since the exact nature of a monotonic transfer function may not be known, the parameters can be based on estimates of the input and output values that correspond to the extremes of the active region of the transfer function.

At 502, the modified binary search method 500 can determine a current input value (CURRENT_INPUT) as a value halfway between the maximum input value (MAX) and the minimum input value (MIN) of the active region of the transfer function. It is understood that other values between the minimum input value (MIN) and the maximum input value (MAX) can be selected without departing from the scope of the present subject matter.

At 503, the modified binary search method 500 can apply the current input value (CURRENT_INPUT) as an input to the monotonic function and measure an output value (OUT). At 204, the binary search method 500 can calculate an error (ERR) as the absolute value of the difference between the target output value (TARGET) and the output value (OUT) corresponding to the current input (CURRENT_INPUT). At 505, the error (ERR) can be compared to the accuracy value (ACCURACY).

When the error (ERR), at 505, is greater than or equal to the accuracy value (ACCURACY), the modified binary search method 500, at 506, can compare the output value (OUT) to the target output value (TARGET). When the output value (OUT), at 506, is greater than or equal to the target output value (TARGET) (e.g., indicating that a target output value (TARGET) is greater than or equal to an output value (OUT) associated with previously set maximum input value (MAX)), the maximum input value (MAX), at 507, can be updated to be equal to the current input value (CURRENT_INPUT). Conversely, when the output value (OUT), at 506, is less than the target output value (TARGET) (e.g., indicating that a target output value (TARGET) is less than a previously set maximum input value (MAX)), the minimum input value (MIN), at 508, can be updated to be equal to the current input value (CURRENT_INPUT).

When the error (ERR), at 505, is less than the accuracy parameter value (ACCURACY), the modified binary search method 500, at 510, can compare the output value (OUT) to the target output value (TARGET). When the output value (OUT), at 510, is greater than or equal to the target output value (TARGET) (e.g., indicating that a target output value (TARGET) is greater than or equal to an output value (OUT) associated with a previously set minimum input value (MIN)), the modified binary search method 500, at 509, can indicated that the current input value (CURRENT_INPUT) corresponds to, or is associated with, an end of the active region of the monotonic function, such as a low input limit of the active region.

When the output value (OUT), at 510, is less than the target output value (TARGET) (e.g., indicating that a target output value (TARGET) is less than an output value (OUT) associated with a previously set minimum input value (MIN)), the minimum input value (MIN), at 508, can be updated to be equal to the current input value (CURRENT_INPUT). After updating the maximum input value (MAX), at 507, or the minimum input value (MIN), at 508, the modified binary search method 500 can determine the current input value (CURRENT_INPUT) at 502.

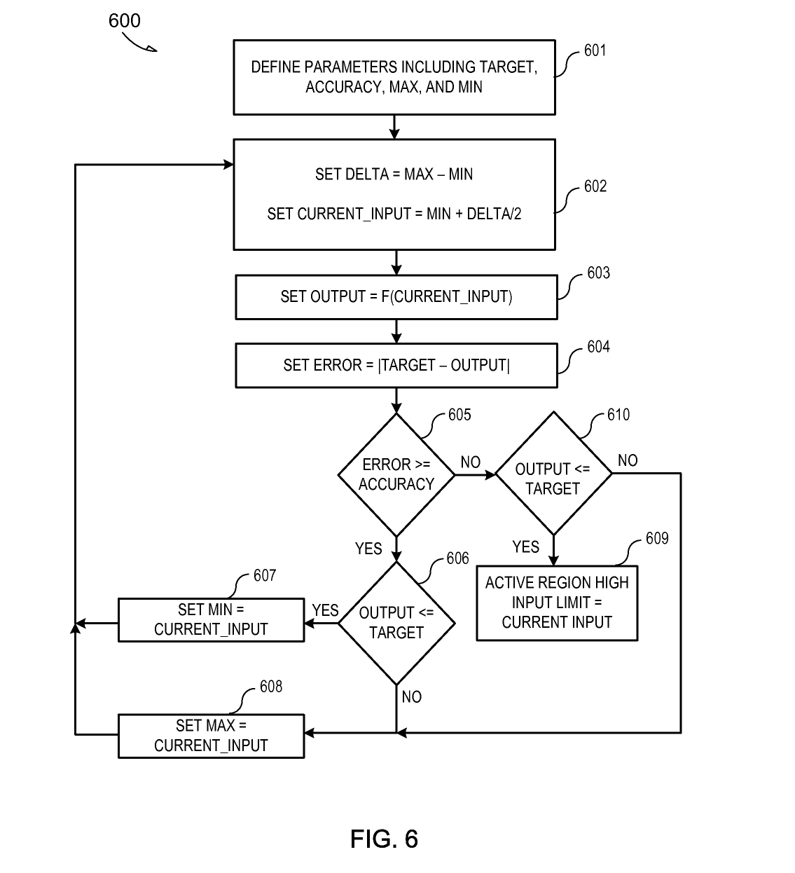

FIG. 6 illustrates generally a flowchart of an example modified binary search method 600 configured to identify an input value corresponding to an end of an active region associated with a monotonic transfer function. In the example of FIG. 6, the example modified binary search method 600 can search for a highest input value associated with the active region.

At 601, one or more parameters can be set or selected including at least one of a target output value at the end of the active region (TARGET), an accuracy value (ACCURACY), a maximum input value at the end of the active region (MAX), or a minimum input value at an end of the active region (MIN). Since the exact nature of a monotonic transfer function may not be known, the parameters can be based on estimates of the input and output values that correspond to the extremes of the active region of the transfer function.

At 602, the modified binary search method 600 can determine a current input value (CURRENT_INPUT) as a value halfway between the maximum input value (MAX) and the minimum input value (MIN) of the active region of the transfer function. It is understood that other values between the minimum input value (MIN) and the maximum input value (MAX) can be selected without departing from the scope of the present subject matter.

At 603, the modified binary search method 600 can apply the current input value (CURRENT_INPUT) as an input to the monotonic function and measure an output value (OUT). At 604, the binary search method 600 can calculate an error (ERR) as the absolute value of the difference between the target output value (TARGET) and the output value (OUT) corresponding to the current input (CURRENT_INPUT). At 605, the error (ERR) can be compared to the accuracy value (ACCURACY).

When the error (ERR), at 605, is greater than or equal to the accuracy value (ACCURACY), the modified binary search method 600, at 606, can compare the output value (OUT) to the target output value (TARGET). When the output value (OUT), at 606, is less than or equal to the target output value (TARGET) (e.g., indicating that a target output value (TARGET) is less than or equal to an output value (OUT) associated with previously set maximum input value (MAX)), the minimum input value (MIN), at 607, can be updated to be equal to the current input value (CURRENT_INPUT). Conversely, when the output value (OUT), at 606, is greater than the target output value (TARGET) (e.g., indicating that a target output value (TARGET) is greater than a previously set maximum input value (MAX)), the maximum input value (MAX), at 608, can be updated to be equal to the current input value (CURRENT_INPUT).

When the error (ERR), at 605, is less than the accuracy parameter value (ACCURACY), the modified binary search method 600, at 610, can compare the output value (OUT) to the target output value (TARGET). When the output value (OUT), at 610, is less than or equal to the target output value (TARGET) (e.g., indicating that a target output value (TARGET) is less than or equal to an output value (OUT) associated with a previously set minimum input value (MIN)), the modified binary search method 600, at 609, can indicated that the current input value (CURRENT_INPUT) corresponds to, or is associated with, an end of the active region of the monotonic function, such as a high input limit of the active region.

When the output value (OUT), at 610, is greater than the target output value (TARGET) (e.g., indicating that a target output value (TARGET) is greater than an output value (OUT) associated with a previously set minimum input value (MIN)), the minimum input value (MIN), at 608, can be updated to be equal to the current input value (CURRENT_INPUT). After updating the minimum input value (MIN), at 607, or the maximum input value (MAX), at 608, the modified binary search method 600 can determine the current input value (CURRENT_INPUT) at 602.

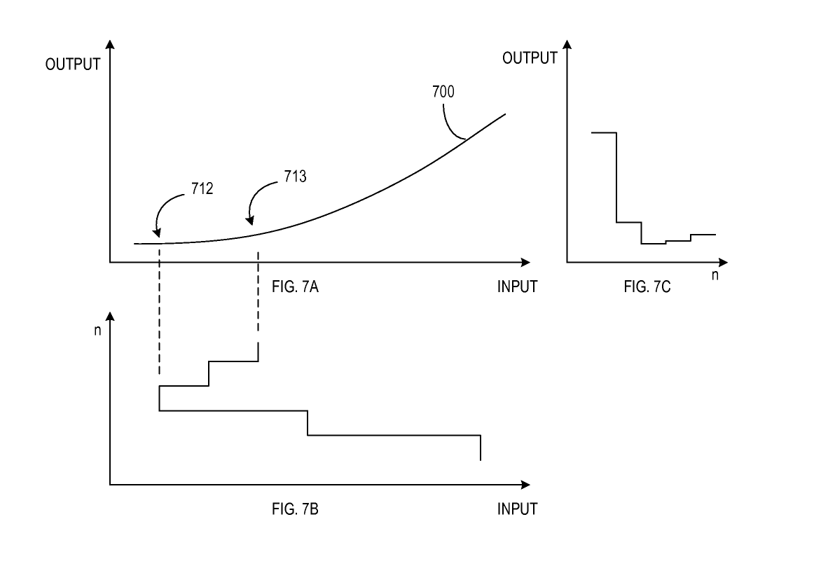

FIGS. 7A-7C illustrate generally plots of an example modified binary search method. FIG. 7A illustrates generally an example of an end portion of a monotonic transfer function 700 corresponding to low input values. FIG. 7B illustrates generally example input values of the monotonic transfer function 700 that can be calculated at each iteration (n) using the modified binary method. FIG. 7C illustrates generally output values of the monotonic transfer function 700 corresponding to the example input values at each iteration (n) of the modified binary search method. The plots in FIGS. 7A-7C illustrate that the modified binary search method disclosed herein can avoid identifying a false end to an active region of a monotonic transfer function, such as a false bottom end 712 of the monotonic transfer function 700. The input value corresponding to the false end of the monotonic transfer function 700 can trigger the completion of an unmodified binary search method, such as the binary search method 200 illustrated in FIG. 2. The additional steps of the modified binary search method disclosed herein can avoid the false end of the monotonic transfer function 700 and can identify an input value closer to the true end 713 of the active region within the accuracy parameter of the target output value representing the estimated end of the active region of the monotonic transfer function 700.

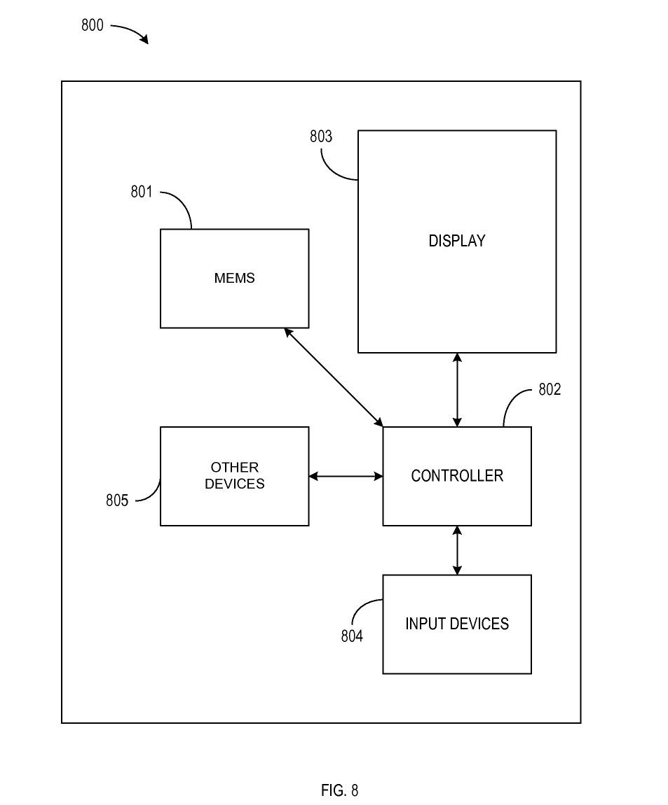

FIG. 8 illustrates generally an example MEMS system 800 including a MEMS device 801 and a controller 802. In certain examples, the MEMS device 801 can provide sensory information to the controller 802 and the controller 802 can receive the sensory information and use the sensory information to control one or more other devices. In some examples, the MEMS device 801 can include an actuator and the controller 802 can provide command signals or control signals to the MEMS device 801 to control actuation of the MEMS device 801. Robust control or accurate sensing can depend on accurate modeling of the MEMS device 801 transfer function. In some examples, the MEMS device 801 can include a monotonic transfer function. In certain examples, the controller 802, or a controller integrated with the MEMS device, can build an accurate transfer function model of the MEMS device 801 by searching for the extreme limits of an active region of the monotonic transfer function of the MEMS device 801. In certain examples, the controller 802, or a controller integrated with the MEMS device, can receive parameters associated with estimated locations along the transfer function path and can execute a modified binary search method, such as discussed above, to find one or more ends of the active region of the monotonic transfer function of the MEMS device 801. In certain examples, the controller 802, or a controller integrated with the MEMS device, can be configured to perform the modified binary search method using, hardware, software, firmware, or combinations thereof.

In certain examples, the MEMS device 801 can include a sensor. For example, the MEMS device 801 can include, but is not limited to, a sensor for movement, acceleration, orientation, sound, visible light, or other electromagnetic radiation. In some examples, the MEMS device 801 can include an actuator, such as a lens actuator.

In some examples, the system 800 can include a display 803 to display information based on control information for the MEMS device 801 or sense information from or for the MEMS device 801. In certain examples, the system 800 can include one or more input devices 804. In some examples, the input devices 804 can include, but are not limited to, a camera, a light sensor, a keyboard, a touch pad, etc., to sense information from or for the MEMS device 801 or to program the controller 802. In certain examples, the system 800 can include one or more other devices 805. In some examples, the other devices 805 can include, but are not limited to, wireless communication equipment, actuators, lights, transducers (e.g., audio transducers), etc. In certain examples, the system 800 can include a mobile electronic device, such as a cell phone or other personal electronic device powered by a battery.

### Additional Notes & Examples

In Example 1, a method can include receiving a target value and an accuracy range for an active region of a transfer function of a MEMS device, selecting a first input value, applying the first input value to the transfer function of the MEMS device to generate a first output value, identifying that the first output value is within the accuracy range of the target value, selecting a second input value using the first input value when the first output value is within an asymptotic region of the transfer function of the MEMS device, and associating the first input value with the target value when the output value is within the active region of the transfer function of the MEMS device.

In Example 2, the selecting the second input value of Example 1 optionally includes identifying that the target value is closer to the active region than the first output along a path of the transfer function.

In Example 3, the method of any one or more of Examples 1-2 optionally includes applying the second input value to the transfer function of the MEMS device to generate a second output value, identifying that the second output value is within the accuracy range of the target value, and associating the second input value with the target value when the output value is within the active region of the transfer function of the MEMS device.

In Example 4, the method of any one or more of Examples 1-3 optionally includes selecting a third input value when the first output value is not within the accuracy range of the target value.

In Example 5, the method of any one or more of Examples 1-4 optionally includes receiving a minimum input parameter and a maximum input parameter for the transfer function of the MEMS device.

In Example 6, the selecting the first input value of any one or more of Examples 1-5 optionally includes selecting the first input value as a value halfway between a value of the minimum input parameter and a value of the maximum input parameter.

In Example 7, the selecting the second input value of any one or more of Examples 1-6 optionally includes updating the value of at least one of the minimum parameter or the maximum parameter with the first input value. In Example 8, the selecting the second input value of any one or more of

Examples 1-7 optionally includes selecting a value between, such as a value halfway between, in certain examples, the value of the updated parameter and the value of one of the minimum parameter or the maximum parameter.

In Example 9, a MEMS system can include a MEMS actuator, and a MEMS controller configured to receive a target value and an accuracy range for an active region of a transfer function of a MEMS device, select a first input value, apply the first input value to the transfer function of the MEMS device to generate a first output value, identify that the first output value is within the accuracy range of the target value, select a second input value using the first input value when the first output value is within an asymptotic region of the transfer function of the MEMS device, and associate the first input value with the target value when the output value is within the active region of the transfer function of the MEMS device.

In Example 10, the MEMS controller of any one or more of Examples 1-9 optionally is configured to identify that the target value is closer to the active region than the first output along a path of the transfer function before the second input value is selected.

In Example 11, the MEMS controller of any one or more of Examples 1-10 optionally is configured to apply the second input value to the transfer function of the MEMS device to generate a second output value, to identify that the second output value is within the accuracy range of the target value, and to associate the second input value with the target value when the output value is within the active region of the transfer function of the MEMS device.

In Example 12, the MEMS controller of any one or more of Examples 1-11 optionally is configured to select a third input value when the first output value is not within the accuracy range of the target value.

In Example 13, the MEMS controller of any one or more of Examples 1-12 optionally is configured to receive a minimum input parameter and a maximum input parameter for the transfer function of the MEMS device.

In Example 14, the MEMS controller of any one or more of Examples 1-13 optionally is configured to select the first input value as a value between a value of the minimum input parameter and a value the maximum input parameter.

In Example 15, the MEMS controller of any one or more of Examples 1-14 optionally is configured to update the value of at least one of the minimum parameter or the maximum parameter with the first input value.

In Example 16, the MEMS controller of any one or more of Examples 1-15 optionally is configured to select the second input value as a value between the value of the updated parameter and the value of one of the minimum parameter or the maximum parameter.

In Example 17, a non-transitory machine-readable medium having instructions to identify an input value to a transfer function, the input value associated with a target value, the instructions, when executed by a MEMS device, can cause the MEMS device to receive a target value and an accuracy range for an active region of a transfer function of the MEMS device, select a first input value, apply the first input value to the transfer function of the MEMS device to generate a first output value, identify that the first output value is within the accuracy range of the target value, select a second input value using the first input value when the first output value is within an asymptotic region of the transfer function of the MEMS device, and associate the first input value with the target value when the output value is within the active region of the transfer function of the MEMS device.

In Example 18, the instruction to select the second input value of any one or more of examples 1-17 optionally includes an instruction to identify that the target value is closer to the active region than the first output along a path of the transfer function.

In Example 19, the non-transitory machine-readable medium of any one or more of Examples 1-18 optionally include instructions that, when executed by the MEMS device, cause the MEMS device to apply the second input value to the transfer function of the MEMS device to generate a second output value, identify that the second output value is within the accuracy range of the target value, and associate the first input value with the target value when the output value is within the active region of the transfer function of the MEMS device.

In Example 20, the non-transitory machine-readable medium of any one or more of Examples 1-19 optionally include instructions that, when executed by the MEMS device, cause the MEMS device to select a second input value when the first output value is not within the accuracy range of the target value.

In Example 21, the non-transitory machine-readable medium of any one or more of Examples 1-20 optionally include instructions that, when executed by the MEMS device, cause the MEMS device to receive a minimum input parameter and a maximum input parameter for the transfer function of the MEMS device.

In Example 22, the non-transitory machine-readable medium of any one or more of Examples 1-21 optionally includes an instruction to select the first input value as a value between, such as halfway between in certain examples, a value of the minimum input parameter and a value the maximum input parameter.

In Example 23, the non-transitory machine-readable medium of any one or more of Examples 1-22 optionally includes an instruction to update the value of at least one of the minimum parameter or the maximum parameter with the first input value.

In Example 24, the non-transitory machine-readable medium of any one or more of Examples 1-23 optionally includes an instruction to select a value between, such as halfway between in certain examples, the value of the updated parameter and the value of one of the minimum parameter or the maximum parameter.

Example 25 can include, or can optionally be combined with any portion or combination of any portions of any one or more of Examples 1 through 24 to include, subject matter that can include means for performing any one or more of the functions of Examples 1 through 24, or a machine-readable medium including instructions that, when performed by a machine, cause the machine to perform any one or more of the functions of Examples 1 through 24.

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. In certain examples, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. A method, comprising:
receiving a target value and an accuracy range for an active region of a transfer function of a MEMS device;
selecting a first input value;
applying the first input value to the transfer function of the MEMS device to generate a first output value;
identifying that the first output value is within the accuracy range of the target value;
selecting a second input value using the first input value when the first output value is within an asymptotic region of the transfer function of the MEMS device; and
associating the first input value with the target value when the output value is within the active region of the transfer function of the MEMS device.

2. The method of claim 1, wherein the selecting the second input value includes identifying that the target value is closer to the active region than the first output along a path of the transfer function.

3. The method of claim 1, including:
applying the second input value to the transfer function of the MEMS device to generate a second output value;
identifying that the second output value is within the accuracy range of the target value; and
associating the second input value with the target value when the output value is within the active region of the transfer function of the MEMS device.

4. The method of claim 1, including:
selecting a third input value when the first output value is not within the accuracy range of the target value.

5. The method of claim 1, including:
receiving a minimum input parameter and a maximum input parameter for the transfer function of the MEMS device.

6. The method of claim 5, wherein the selecting the first input value includes selecting the first input value as a value halfway between a value of the minimum input parameter and a value of the maximum input parameter.

7. The method of claim 5, wherein the selecting the second input value includes updating the value of at least one of the minimum parameter or the maximum parameter with the first input value.

8. The method of claim 7, wherein the selecting the second input value includes selecting a value halfway between the value of the updated parameter and the value of one of the minimum parameter or the maximum parameter.

9. A MEMS system comprising:
a MEMS actuator; and
a MEMS controller configured to:
receive a target value and an accuracy range for an active region of a transfer function of a MEMS device;
select a first input value;
apply the first input value to the transfer function of the MEMS device to generate a first output value;
identify that the first output value is within the accuracy range of the target value;
select a second input value using the first input value when the first output value is within an asymptotic region of the transfer function of the MEMS device; and
associate the first input value with the target value when the output value is within the active region of the transfer function of the MEMS device.

10. The MEMS system of claim 9, wherein the MEMS controller is configured to identify that the target value is closer to the active region than the first output along a path of the transfer function before the second input value is selected.

11. The MEMS system of claim 9, wherein the MEMS controller is configured to:
apply the second input value to the transfer function of the MEMS device to generate a second output value;
identify that the second output value is within the accuracy range of the target value; and
associate the second input value with the target value when the output value is within the active region of the transfer function of the MEMS device.

12. The MEMS system of claim 9, wherein the MEMS controller is configured to select a third input value when the first output value is not within the accuracy range of the target value.

13. The MEMS system of claim 9, wherein the MEMS controller is configured to receive a minimum input parameter and a maximum input parameter for the transfer function of the MEMS device.

14. The MEMS system of claim 13, wherein the MEMS controller is configured to select the first input value as a value halfway between a value of the minimum input parameter and a value the maximum input parameter.

15. The MEMS system of claim 13, wherein the MEMS controller is configured to update the value of at least one of the minimum parameter or the maximum parameter with the first input value.

16. The MEMS system of claim 15, wherein the MEMS controller is configured to select the second input value as a value halfway between the value of the updated parameter and the value of one of the minimum parameter or the maximum parameter.

17. A non-transitory machine-readable medium having instructions to identify an input value to a transfer function, the input value associated with a target value, the instructions, when executed by a MEMS device, cause the MEMS device to:
receive a target value and an accuracy range for an active region of a transfer function of the MEMS device;
select a first input value;
apply the first input value to the transfer function of the MEMS device to generate a first output value;
identify that the first output value is within the accuracy range of the target value;
select a second input value using the first input value when the first output value is within an asymptotic region of the transfer function of the MEMS device; and
associate the first input value with the target value when the output value is within the active region of the transfer function of the MEMS device.

18. The non-transitory machine-readable medium of claim 17, wherein the instruction to select the second input value includes an instruction to identify that the target value is closer to the active region than the first output along a path of the transfer function.

19. The non-transitory machine-readable medium of claim 17, including instructions that, when executed by the MEMS device, cause the MEMS device to:
apply the second input value to the transfer function of the MEMS device to generate a second output value;
identify that the second output value is within the accuracy range of the target value; and
associate the first input value with the target value when the output value is within the active region of the transfer function of the MEMS device.

20. The non-transitory machine-readable medium of claim 17, including instructions that, when executed by the MEMS device, cause the MEMS device to select a second input value when the first output value is not within the accuracy range of the target value.

21. The non-transitory machine-readable medium of claim 17, including instructions that, when executed by the MEMS device, cause the MEMS device to receive a minimum input parameter and a maximum input parameter for the transfer function of the MEMS device.

22. The non-transitory machine-readable medium of claim 21, wherein the instruction to select the first input value includes an instruction to select the first input value as a value halfway between a value of the minimum input parameter and a value the maximum input parameter.

23. The non-transitory machine-readable medium of claim 21, wherein the instruction to select the second input value includes an instruction to update the value of at least one of the minimum parameter or the maximum parameter with the first input value.

24. The non-transitory machine-readable medium of claim 23, wherein the instruction to select the second input value includes an instruction to select a value halfway between the value of the updated parameter and the value of one of the minimum parameter or the maximum parameter.
